(19) United States
(12) Patent Application Publication
(10) Pub. No.: US 2026/0213128 A1
(43) Pub. Date: Jul. 23, 2026

(54) Beam Apparatus, Lamella Extraction Apparatus, Lamella Observation System, and Lamella Preparation Method

(71) Applicant: Hitachi High-Tech Corporation, Minato-ku, Tokyo (JP)

(72) Inventors: Tsukasa MORISHITA, Tokyo (JP); Shoichi HASEGAWA, Tokyo (JP); Yutaka IKKU, Tokyo (JP); Yugo ONODA, Tokyo (JP)

(21) Appl. No.: 19/141,573

(22) PCT Filed: Dec. 20, 2022
(86) PCT No.: PCT/JP2022/046768

§ 371 Date: Jun. 20, 2025

(51) Int. Cl. H01J 37/305; H01J 37/20; H01J 37/26; H01J 37/28

(52) U.S. Cl. CPC H01J 37/3053; H01J 37/20; H01J 37/26; H01J 37/28; H01J 2237/202; H01J 2237/31745; H01J 2237/31749

(57) ABSTRACT

A lamella processing method is provided that enables safe lifting-out (picking up) of a lamella while maintaining throughput of lamella preparation using a white light interference microscope as an observation unit. A lamella preparation method for extracting a lamella from a sample by using a lamella transfer part includes: a process of preparing a mark on a sloped surface prepared by lamella processing; a process of acquiring surface information by performing microscopic measurement on the mark; and a process of controlling a sample stage or the lamella transfer part to reduce a distance between a position of the mark and a position of the lamella transfer part.

### TECHNICAL FIELD

The present disclosure relates to a lamella preparation method and a lamella observation system, and particularly to a technique for preparing a TEM observation sample (lamella).

### BACKGROUND ART

With the miniaturization of semiconductors, a transmission electron microscope (TEM) is used as a high-resolution observation unit for inspecting an integrated circuit manufacturing process. Preparation of a TEM sample for TEM observation includes a step of preparing a lamella (sample piece) by thinning a region including an observation target portion using a focused ion beam (FIB) or the like, and a step of mounting the lamella on a TEM observation lamella holder (sample piece holder). A micro sampling method using an FIB-SEM composite apparatus, which is a composite apparatus of a focused ion beam apparatus and a scanning electron microscope (SEM), a method using a glass probe and an optical microscope, or the like is used to mount the lamella on the lamella holder (see PTL 1).

In a method in the related art in which pickup is performed using a probe while observing a processing region of a sample with an FIB-SEM composite apparatus or an optical microscope, a position on a plane of an observation object can be grasped in any observation method, but a position in a depth direction cannot be grasped, and thus the probe may come into contact with the lamella or sample, and there is a risk of breakage of the lamella or the probe or loss of the lamella.

### CITATION LIST

### Patent Literature

PTL 1: JP2001-141620A

### SUMMARY OF INVENTION

### Technical Problem

When implementing a method of picking up a prepared lamella using tweezers and mounting the lamella on a lamella holder, it is important to grasp a positional relationship between the tweezers and the sample since the tweezers and the sample may collide with each other.

A white light interference microscope is one of means for grasping the positional relationship between the tweezers and the sample. The white light interference microscope can acquire a three-dimensional (3D) image by driving an optical system including an interferometer in a focus direction and detecting a generation position of an interference pattern, and thus can be used as a position grasping means. However, since interfering light does not reach the optical system, there is a problem that a position of a sloped surface sloped more than an opening angle of the optical system cannot be grasped. On the other hand, in the lamella preparation, in order to prepare a sloped surface sloped less than the opening angle of the optical system of the white light interference microscope, there is a problem that the processing time becomes long and the throughput of the lamella preparation process is reduced.

An object of the present disclosure is to provide a lamella processing method that enables safe lifting-out (picking up) of a lamella while maintaining the throughput of lamella preparation using a white light interference microscope as an observation means.

### Solution to Problem

According to an aspect of the present disclosure, there is provided a lamella preparation method for extracting a lamella from a sample by using a lamella transfer part, the method including: a process of preparing a mark on a sloped surface (a sloped surface dug toward a lamella preparation scheduled portion of the sample) prepared by lamella processing; a process of acquiring surface information by performing microscopic measurement on the mark; and a process of controlling a sample stage or the lamella transfer part to reduce a distance between a position of the mark and a position of the lamella transfer part. Accordingly, it is possible to accurately grasp shape information of a processing region including a depth at the time of lamella pickup and to prevent tweezers from coming into contact with the sample or the processing region at the time of pickup even on the sloped surface sloped more greatly than an opening angle of an optical system of a white light interference microscope.

### Advantageous Effects of Invention

According to an aspect of the present disclosure, even when a sloped surface prepared by lamella processing is sloped more greatly than an opening angle of an optical system, it is possible to safely lift out a lamella using a white light interference microscope as an observation unit.

### BRIEF DESCRIPTION OF DRAWINGS

FIG. 1 is a configuration diagram of a lamella observation system according to an embodiment.

FIG. 2 is a configuration diagram of an FIB-SEM composite apparatus according to the embodiment.

FIG. 3 is a flowchart of a lamella preparation method showing steps of lamella preparation and a lift-out operation according to the embodiment.

FIG. 4 is a view illustrating a lamella processing region for lifting-out according to the embodiment.

FIG. 5 is a configuration diagram of a lamella lift-out apparatus according to the embodiment.

FIG. 6 is a configuration diagram of a TEM observation lamella holder according to the embodiment.

FIG. 7 illustrates a microscopic image of tweezers and a lamella processing region obtained by the lamella lift-out apparatus according to the embodiment.

FIG. 8 is a microscopic image of the tweezers and slope portion marking obtained the lamella lift-out apparatus according to the embodiment.

FIG. 9 is a conceptual diagram illustrating processing of a mark according to the embodiment.

FIG. 10 is a table illustrating shapes of the mark according to the embodiment.

FIG. 11 is a diagram illustrating processing of a slope by sputtering according to the embodiment.

FIG. 12 is a diagram illustrating processing of a mark by sputtering according to the embodiment.

FIG. 13 is a conceptual diagram illustrating a case where light L1 described with reference to FIG. 5 is applied to a sloped surface of a slope and a recessed fine processing surface of a mark.

FIG. 14 is a conceptual diagram illustrating a state in which tweezers are moved to a position immediately before a gripping position of a lamella according to the embodiment.

### DESCRIPTION OF EMBODIMENTS

Hereinafter, embodiments will be described with reference to the drawings.

### Embodiment 1

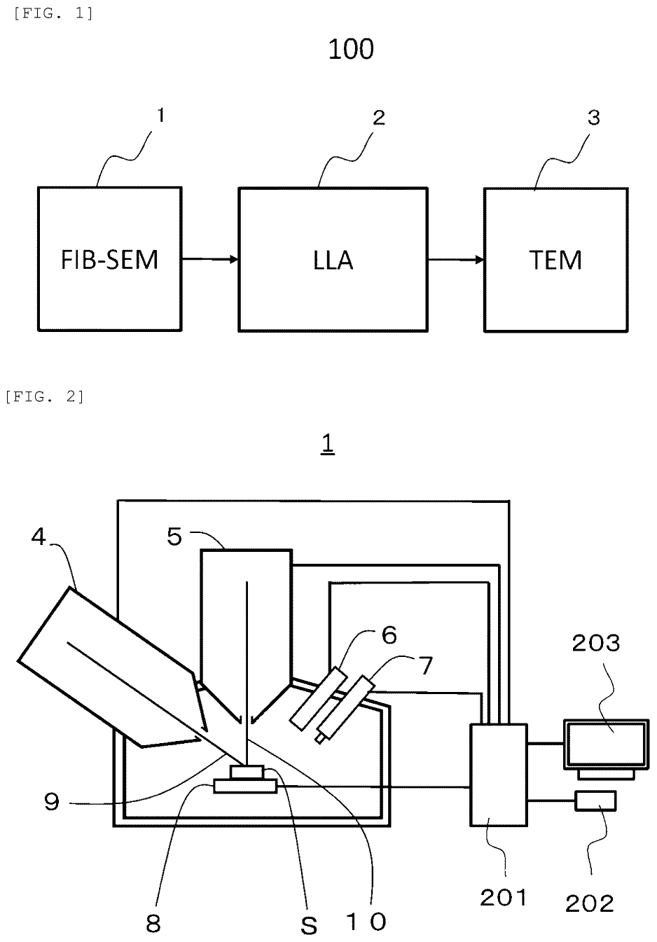

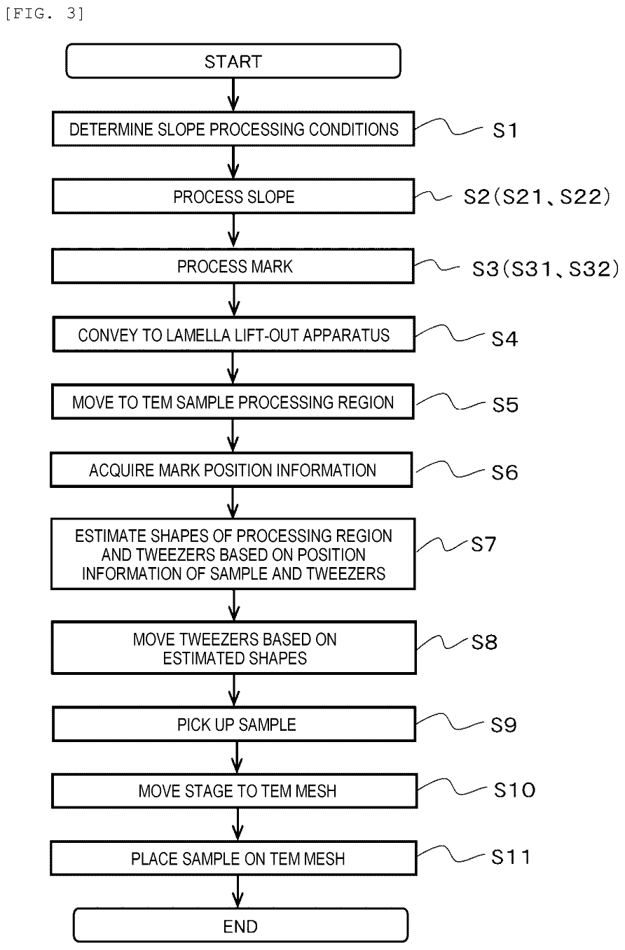

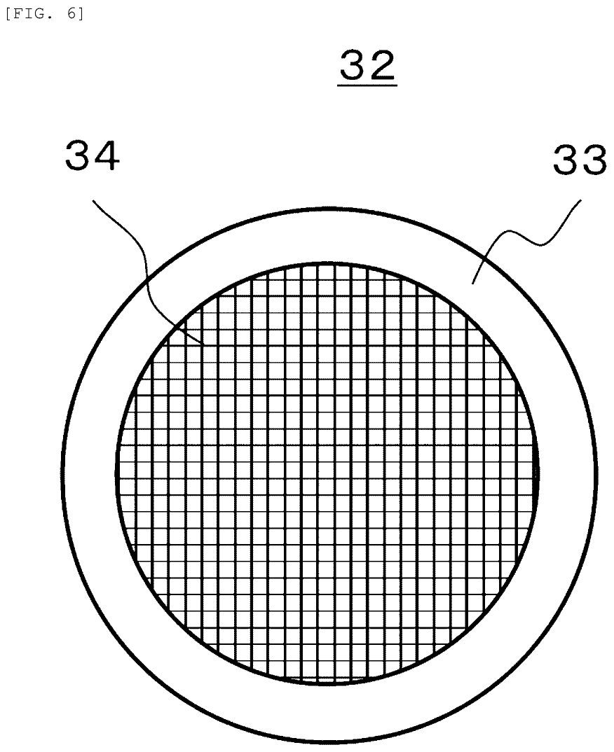

FIG. 1 is a configuration diagram of a lamella observation system according to an embodiment. FIG. 2 is a configuration diagram of an FIB-SEM composite apparatus according to the embodiment. FIG. 5 is a configuration diagram of a lamella lift-out apparatus according to the embodiment. FIG. 6 is a configuration diagram of a TEM observation lamella holder according to the embodiment.

A lamella observation system according to the embodiment includes an FIB-SEM composite apparatus (a composite apparatus of focused ion beam (FIB) apparatus-scanning electron microscope (SEM) ) 1, a lamella lift-out apparatus (LLA) 2, and a transmission electron microscope (TEM) apparatus 3. The scanning electron microscope includes a scanning electron microscope lens barrel.

A lamella preparation process and a mark preparation process are performed by the FIB-SEM composite apparatus 1. A mark observation process and a lamella extraction process are performed by the lamella lift-out apparatus 2. A lamella observation process is performed by the TEM apparatus 3.

That is, the lamella observation system 100 includes
the FIB-SEM composite apparatus 1 serving as a beam apparatus configured to prepare a mark on a sloped surface (object) dug toward a lamella prepared in a sample by lamella preparation processing,
the lamella lift-out apparatus 2 serving as a lamella extraction apparatus including a microscope for observing the mark, and configured to observe the mark and extract the lamella from the sample based on the mark, and
the TEM apparatus 3 serving as a transmission electron microscope configured to observe the extracted lamella.

Here, the FIB-SEM composite apparatus 1 may be referred to as a focused ion beam apparatus that prepares a sample for a transmission electron microscope by performing irradiation with a focused ion beam.

As illustrated in FIG. 2, the FIB-SEM composite apparatus 1 includes an irradiation optical system 4 of a focused ion beam (FIB) 9, an irradiation optical system 5 of an electron beam (EB) 10, an electron detector 6 that detects secondary charged particles generated from an irradiation object (for example, a sample piece) by irradiation with a charged particle beam (9, 10) from the irradiation optical system 4 or the irradiation optical system 5, a gas gun (deposition gas supply part) 7 that injects a gas for deposition film formation, and a sample holder 8. The FIB-SEM composite apparatus 1 includes a first control device 201 that comprehensively controls an operation of the FIB-SEM composite apparatus 1, a first input device 202 electrically connected to the first control device 201, and a first display device 203 electrically connected to the first control device 201.

A surface of the irradiation object is scanned and irradiated with the focused ion beam 9 by the irradiation optical system 4 of the focused ion beam 9, so that the surface of the irradiation object can be etched by sputtering. Further, by irradiating the surface of the irradiation object with the focused ion beam 9 while injecting the gas from the gas gun 7 that is the deposition gas supply part, a deposition film can be formed at an irradiation position on the surface of the irradiation object. The surface of the irradiation object is scanned and irradiated with the focused ion beam 9, and secondary charged particles such as secondary electrons and secondary ions generated from the irradiation object are detected by the electron detector 6. Signals detected by the electron detector 6 at respective irradiation positions are processed by the first control device 201, so that an image of an irradiation portion on the surface of the irradiation object can be formed. The formed image of the surface of the irradiation object can be displayed on the first display device 203, for example.

The first control device 201 comprehensively controls the operation of the FIB-SEM composite apparatus 1 by a signal received from the first input device 202 such as a mouse or a keyboard, a signal generated by a preset automatic operation control device, or the like. The automatic operation control device may include, for example, a control circuit (CNT) such as a central processing unit (CPU) built in the first control device 201, and an operation control program for automatic operation control processing executed by the control circuit (CNT). When the automatic operation control processing is executed by the control circuit (CNT) in the first control device 201, the FIB-SEM composite apparatus 1 can be automatically operated under the control of the first control device 201.

The first control device 201 can cause the first display device 203 to display an image display screen for displaying image data that is generated according to various types of information on the FIB-SEM composite apparatus 1 and a signal obtained from the electron detector 6, and an operation menu display screen for instructing an operation such as enlargement, reduction, movement, or rotation of each piece of image data. An operator refers to information output from the first display device 203 (such as image data displayed on the image display screen), selects an operation instruction displayed on the operation menu display screen using the first input device 202, and gives an operation command to the first control device 201. Accordingly, the first control device 201 can operate the FIB-SEM composite apparatus 1.

As illustrated in FIG. 5, the lamella lift-out apparatus 2 includes a white light interference microscope 15, a lens barrel drive mechanism 25, a sample stage 26, tweezers 27 for lamella lift-out, and a tweezers drive mechanism 28 that drives the tweezers 27. The white light interference microscope 15 includes a light source 16, a filter 17, a first beam splitter 18, a second beam splitter 19, a first objective lens 20, a second objective lens 21, a fixed mirror 22, and a photodetector 24. That is, the lamella lift-out apparatus 2 as the lamella extraction apparatus includes, as an observation unit, a scanning white light interference microscope on which the light source 16, an interferometer including two objective lenses of the first objective lens 20 and the second objective lens 21, and the photodetector 24 are mounted and which acquires height information from a distribution of detected interference fringes.

The lamella lift-out apparatus 2 further includes a second control device 29 as control unit that comprehensively controls the operation of the lamella lift-out apparatus 2, a second input device 30 connected to the second control device 29, a second display device 31, and a TEM observation lamella holder 32.

The white light interference microscope 15 emits light L0 from the light source 16. The light L0 passes through the filter 17, is then reflected by the first beam splitter 18, and is split by the second beam splitter 19 into light L1 traveling toward a sample S as an object to be measured and reference light L2 traveling toward the fixed mirror 22. The light L1 passes through the first objective lens 20, and the light L1 hits the sample S and is reflected back. Reflected light L1R of the light L1 reflected back by the sample S is combined with the reference light L2, which is reflected from the fixed mirror 22, by the second beam splitter 19, and is detected as interference light L3 by the photodetector 24. An intensity of the interference light L3 changes due to a phase difference between the light L1 and the reference light L2 when combined by the second beam splitter 19, and the interference light intensity is maximized when phases thereof are the same, and the interference light intensity decreases as the phases thereof approach opposite phases. Under a condition that a distance between the second beam splitter 19 and the fixed mirror 22 is constant, the lens barrel drive mechanism 25 moves the photodetector 24, which is an optical interference measurement device, in a Z-axis direction to change a distance of an optical path of the light L1. Accordingly, the phase difference between the light L1 and the reference light L2 is changed, and information on a shape including a Z position of the sample S as the object to be measured is acquired from information on intensity transition of the interference light L3.

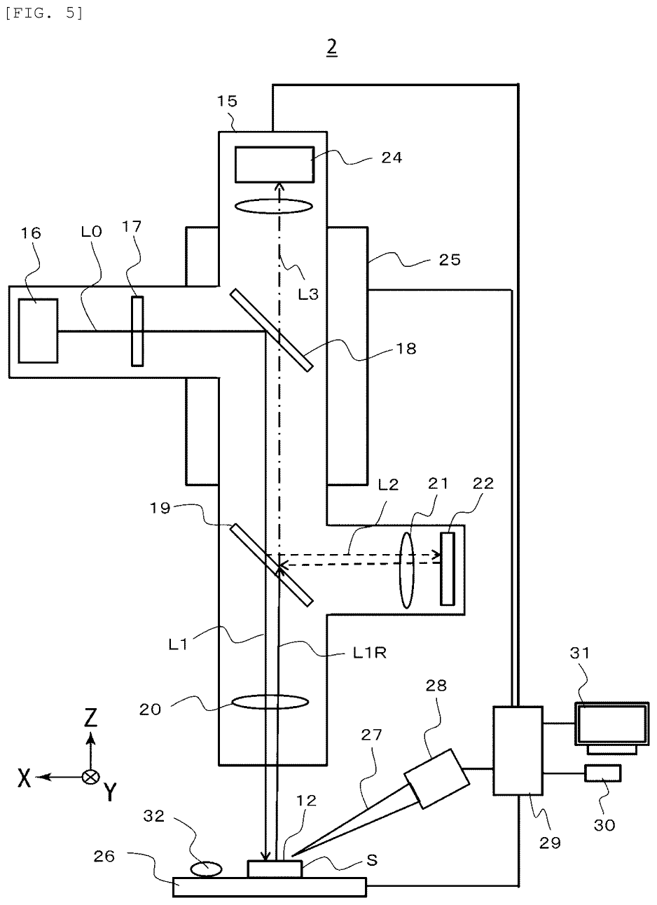

The tweezers 27 sandwich and grip a lamella 12, which is a sample piece, by a pair of arms, for example. The lamella 12 is formed in the sample S as illustrated in FIG. 4. The tweezers 27 may be referred to as a sample transfer part or lamella transfer part. The sample transfer part is not limited to the tweezers 27, and for example, a glass probe or a suction probe may be used. The tweezers drive mechanism 28 translates the tweezers 27 sloped at any angle in an X-axis direction, a Y-axis direction, and the Z-axis direction in this state, or rotates the tweezers 27 about an arm thereof.

The second control device 29 comprehensively controls the operation of the lamella lift-out apparatus 2 by a signal received from the second input device 30 such as a mouse or a keyboard connected thereto, a signal generated by a preset automatic operation control device, or the like. The automatic operation control device may include, for example, a control circuit (CNT) such as a central processing unit (CPU) built in the second control device 29, and an operation control program for automatic operation control processing executed by the control circuit (CNT). When the automatic operation control processing is executed by the control circuit (CNT) in the second control device 29, the lamella lift-out apparatus 2 can be automatically operated under the control of the second control device 29.

The second control device 29 causes the connected second display device 31 to display image data generated according to various types of information on the lamella lift-out apparatus 2 and a signal obtained from the photodetector 24, and a screen for executing operations such as enlargement, reduction, movement, and rotation of each piece of image data. The operator refers to the information output from the second display device 31, gives a command to the second control device 29 using the second input device 30, and operates the lamella lift-out apparatus 2.

As illustrated in FIG. 6, the TEM observation lamella holder 32 includes, for example, a lattice mesh 34 and a grid frame 33 which is provided to surround an outer periphery of the circular mesh 34 in a plan view.

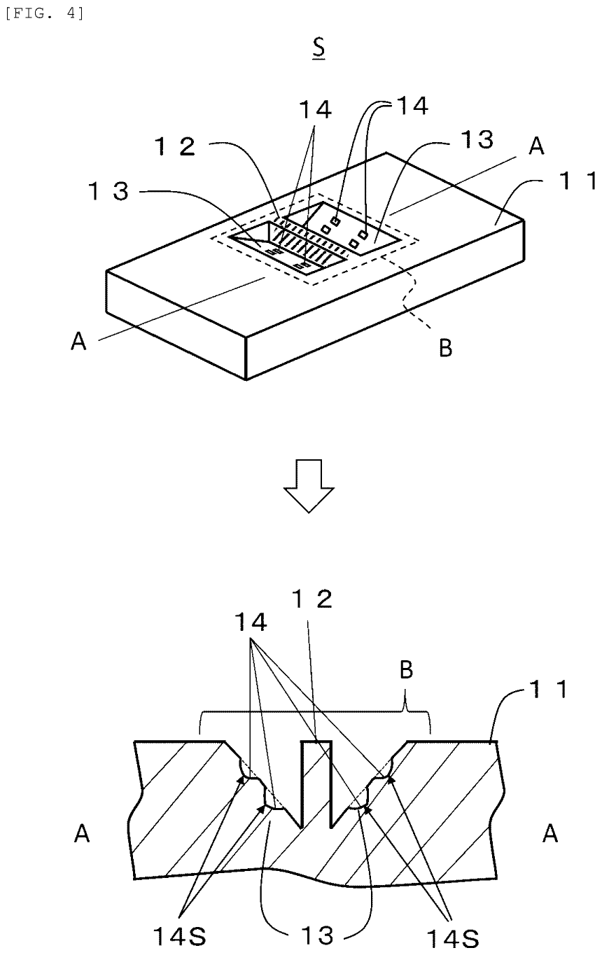

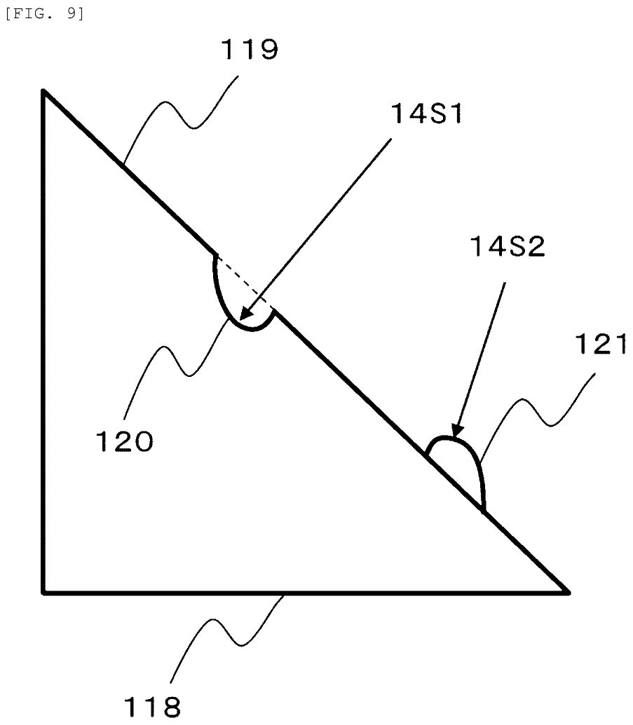

Next, mark processing by the FIB-SEM composite apparatus 1 according to the embodiment of the invention and a use example thereof will be described with reference to a flowchart related to a lamella preparation method in FIG. 3. FIG. 3 is a flowchart of the lamella preparation method showing steps of lamella preparation and a lift-out operation according to the embodiment. FIG. 4 is a partially enlarged view of a lamella processing region for lifting-out formed in the sample according to the embodiment. FIG. 9 is a conceptual diagram illustrating processing of a mark according to the embodiment.

First, a mark 14 formed on a slope 13 in a lamella processing region B will be described with reference to FIG. 4. FIG. 4 illustrates a perspective view of the lamella processing region B and a partial cross-sectional view of the lamella processing region B taken along a line A-A in the perspective view.

As illustrated in FIG. 4, the lamella processing region B is provided on a surface 11 of the sample S such as a semiconductor wafer. The lamella 12 and slopes 13 provided on both sides of the lamella 12 are provided in the lamella processing region B that is a lamella preparation scheduled portion. The slopes 13 are formed by performing irradiation with the focused ion beam 9 using the FIB-SEM composite apparatus 1 and carving a slope by sputtering from two directions with respect to the lamella 12. The slopes 13 can be rephrased as sloped surfaces dug toward a preparation scheduled portion of the lamella 12 on the sample S. In this example, a surface of the slope 13 is irradiated with the focused ion beam 9 using the FIB-SEM composite apparatus 1, and the mark 14 is formed on the surface of the slope 13 by sputtering. In this example, four marks 14 are formed on one slope 13. The number of marks 14 provided on one slope 13 is at least one. The number of marks 14 provided on one slope 13 may be more than one, such as two, three, and five. When estimating a three-dimensional shape of the slope 13, it is preferable to form three or more marks 14 per one surface of the slope 13.

In the method of preparing the lamella 12, a method of preparing a thin piece by performing irradiation with the focused ion beam 9 using the FIB-SEM composite apparatus 1 and carving slopes by sputtering from two directions is widely used. As a method for shortening the processing time without changing a shape of the lamella 12 in this method, an inclination angle of the surface of the slope 13 is increased to reduce a sputtering volume. However, when the inclination angle of the slope is increased, there is a possibility that the slope portion cannot be measured by the photodetector 24 of the white light interference microscope 15 of the lamella lift-out apparatus 2. This is because there is a limit to the inclination angle of the object that can be measured in principle in the microscopic measurement using the white light interference microscope 15.

A relationship between values can be expressed by the following equation (1), θ being a maximum angle that can be taken under a condition in which the reflected light L1R is incident on the objective lens 20 again among angles formed by the optical path of the incident light L1 passing through the objective lens 20 and an optical path of the light L1R reflected by the sample S when the incident light L1 hits the sample S, NA being a numerical aperture of the objective lens 20, and n being a refractive index of a medium existing between the objective lens 20 and the sample S. When the reflected light L1R does not fall within a range of angles up to the maximum angle e due to inclination of the sample S, the reflected light L1R cannot be measured by the photodetector 24 of the white light interference microscope 15.
NA=nsinθ (1)

As illustrated in FIG. 4, the mark 14 used in the embodiment enables detection of the slope 13 at an angle that cannot be normally measured by the photodetector 24 of the white light interference microscope 15. That is, the angle of the sloped surface of the slope 13 is an angle larger than a measurement limit of the white light interference microscope 15 that performs the microscopic measurement. In other words, the sloped surface of the slope 13 is a surface sloped with respect to an optic axis of the incident light L1 emitted by the white light interference microscope 15.

The mark 14 forms a surface different from the surface (also referred to as the sloped surface or a slope surface) of the slope 13. Therefore, even when the reflected light L1R by the surface of the slope 13 does not fall within the range of angles up to the maximum angle θ, the reflected light L1R falls within the range of angles up to the maximum angle e by a surface 14S formed by the mark 14. As a result, the second control device 29 can grasp information on a position of the lamella 12 and information on a position of the slope 13 from the photodetector 24 of the white light interference microscope 15.

The second control device 29 grasps the information on the position (X-axis direction, Y-axis direction) of the lamella 12 and information on the slope 13 in the Z-axis direction (height direction), whereby the tweezers 27 used for pickup can be moved to a position immediately before a gripping position of the lamella 12 by the tweezers 27 without being brought into contact with a sample processing region (processing region of the lamella 12) 10.

In the processing of the mark 14, as illustrated in FIG. 9, a sloped surface (the surface of the slope 13) 119 of a measurement object 118 as the sample S is finely processed to change a shape of the surface of the sloped surface 119, thereby generating a recess processing region 120 or a projection processing region 121 having an angle different from that of the sloped surface 119. Since a portion (reflection surface) having an inclination, at which the reflected light L1R falls within the range of angles up to the maximum angle θ of equation (1), is present on a surface of the recess processing region 120 or the projection processing region 121, the incident light L1 irradiated on the portion can finally reach the photodetector 24 and can be detected.

For example, the recess processing region 120 can be processed by being irradiated with the focused ion beam 9 using the FIB-SEM composite apparatus 1 and being etched by sputtering. Therefore, it can be said that the recess processing region 120 is a recessed fine processing surface (14S1) formed by cutting the surface of the sloped surface 119.

For example, the projection processing region 121 can be processed by forming a deposition film at an irradiation position on the surface of the irradiation object by irradiating the surface of the irradiation object with the focused ion beam 9 while injecting a gas from the gas gun 7 using the FIB-SEM composite apparatus 1. Therefore, it can be said that the projection processing region 121 is a projecting fine processing surface (14S2) formed by applying a deposition film to the surface of the sloped surface 119.

The recessed fine processing surface (14S1) and the projecting fine processing surface (14S2) are configured such that, even when the reflected light L1R from the surface of the slope 13 (the sloped surface 119) does not fall within the range of angles up to the maximum angle θ , the reflected light L1R from the recessed fine processing surface (14S1) and the projecting fine processing surface (14S2) as the surface 14S formed by the mark 14 falls within the range of angles up to the maximum angle θ.

The surface 14S (the recessed fine processing surface 14S1 and the projecting fine processing surface 14S2) formed by the mark 14 has a surface substantially perpendicular to the optic axis of the incident light L1 emitted by the white light interference microscope 15. The surface perpendicular thereto is configured to reflect the incident light L1 so that the reflected light L1R falls within the range of angles up to the maximum angle θ.

That is, the processing of the mark 14 can be regarded as a mark processing process of etching one or more marks or forming a deposition film on a surface of the sloped surface of the slope 13 in order to increase surface roughness of the surface.

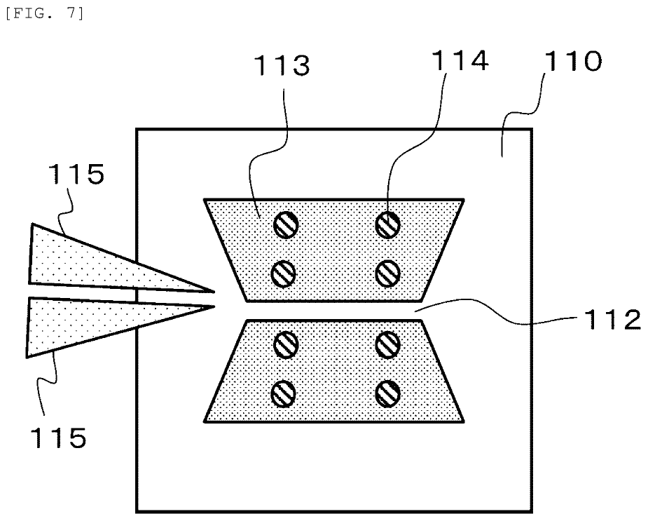

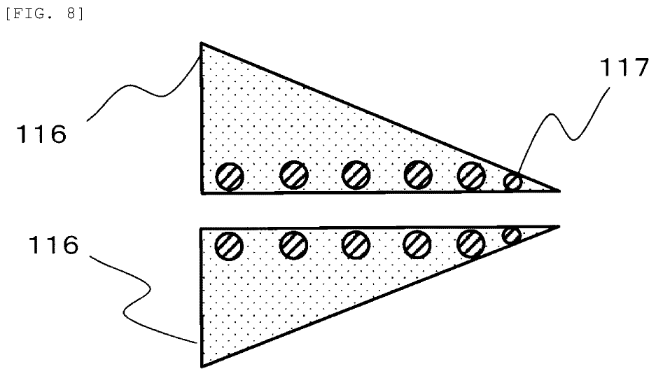

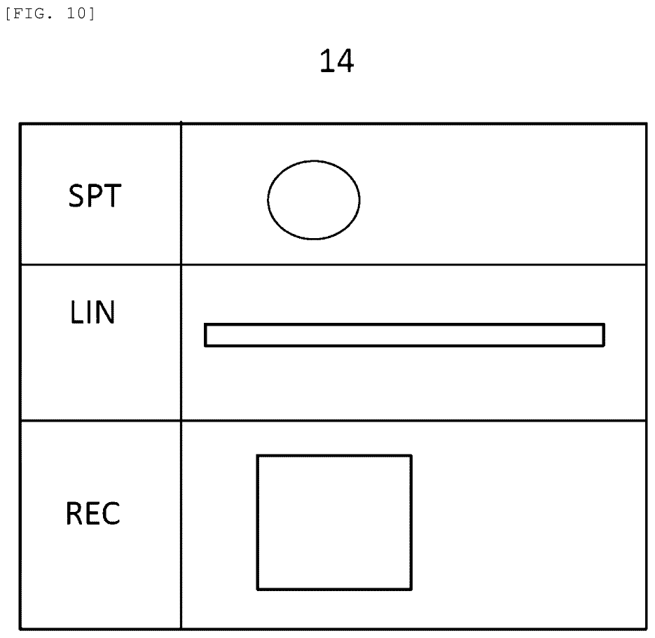

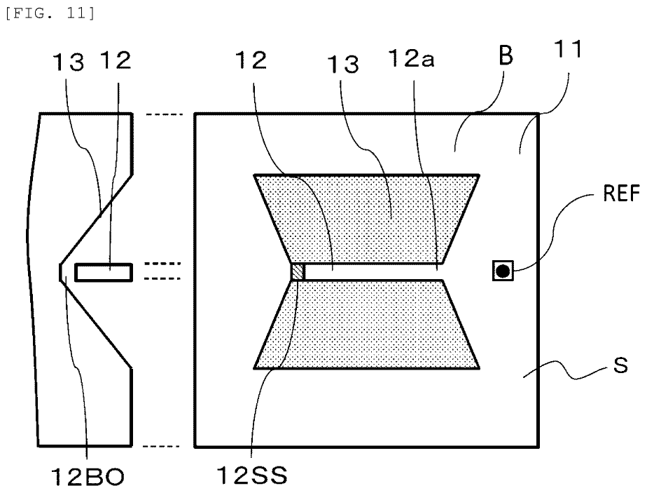

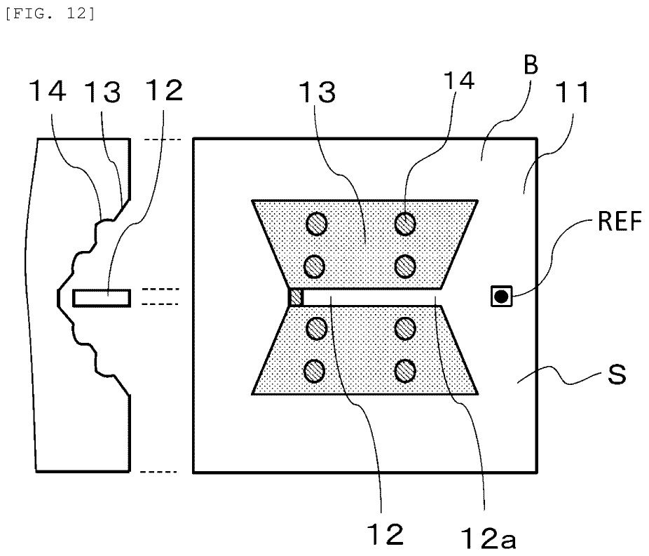

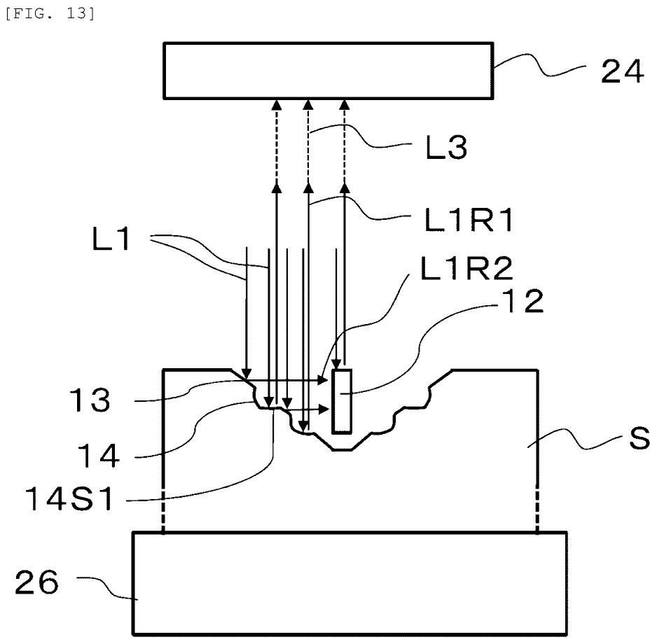

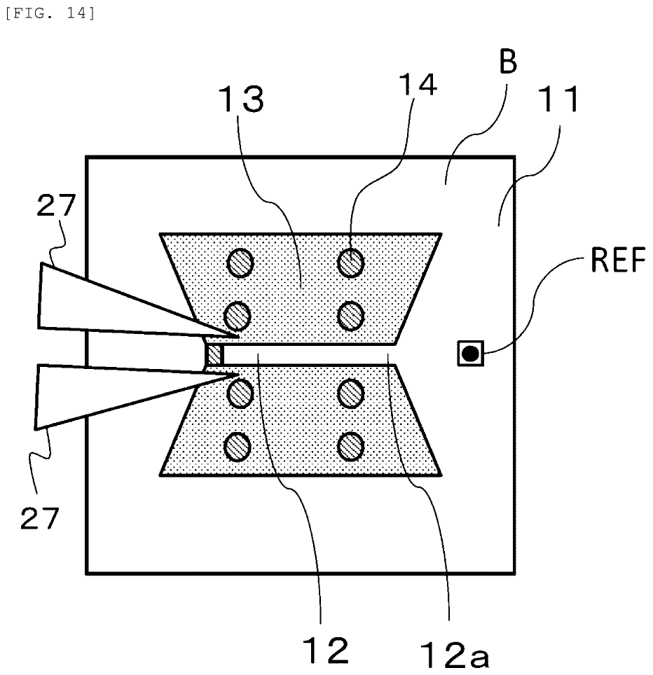

Hereinafter, a description will be made with reference to the flowchart of the lamella preparation method in FIG. 3. In the following example, an example in which the mark 14 is formed by sputtering will be described as a representative example. The mark 14 may be formed by applying a deposition film. FIG. 7 is a microscopic image of the tweezers and the lamella processing region obtained by the lamella lift-out apparatus according to the embodiment. FIG. 10 is a table illustrating shapes of the mark according to the embodiment. FIG. 11 is a diagram illustrating processing of the slope by sputtering according to the embodiment. FIG. 12 is a diagram illustrating processing of the mark by sputtering according to the embodiment. FIG. 13 is a conceptual diagram illustrating a case where the light L1 described with reference to FIG. 5 is applied to the sloped surface of the slope and the recessed fine processing surface of the mark. FIG. 14 is a conceptual diagram illustrating a state in which the tweezers are moved to the position immediately before the gripping position of the lamella according to the embodiment.

### Step S1: Slope Processing Condition Determination Process

First, the operator places the sample S on the sample holder 8 of the FIB-SEM composite apparatus 1.

Next, the first control device 201 controls the irradiation optical system 4 of the focused ion beam 9 to perform irradiation with the focused ion beam 9 while controlling the position of the sample holder 8, and determines processing conditions (a processing position and a processing shape) while checking the sample S by detecting secondary electrons with the electron detector 6. The processing conditions can be input and determined using the first input device 202 while being checked on the first display device 203. The processing conditions include a shape of the surface of the slope 13 in FIG. 4, a final thickness of the lamella 12, a pattern shape of the mark 14, a position of the mark on the surface of the slope 13, the number of marks 14 processed, types of recess processing and projection processing, and the like. As illustrated in FIG. 10, for the pattern shape of the mark 14, it can be selected from a circular (spot shape) mark SPT, a linear (line shape) mark LIN, a rectangular mark REC, and the like. The pattern shape of the mark 14 is not limited to the shapes illustrated in FIG. 10. The pattern shape of the mark 14 may have a processing surface or a reflection surface configured such that the reflected light L1R falls within the range of angles up to the maximum angle θ.

The slope processing conditions set in step S1 are referred to, for example, by an operation control program for the automatic operation control processing executed by the control circuit (CNT) in the first control device 201. Accordingly, it is possible to automatically perform steps S2 and S3.

### Step S2: Slope Processing Process

Next, before processing the slope 13, a process of deposition for protecting the lamella 12 and preparing a reference mark REF for improving processing accuracy in accordance with required specifications of TEM observation is executed (step S21). Thereafter, the first control device 201 performs irradiation with the focused ion beam 9 from the irradiation optical system 4 of the focused ion beam 9 under the processing conditions determined in step S1, and executes the processing process of the slope 13 by sputtering as illustrated in FIG. 11 (step S22). The processing of the slope 13 is a process of forming a sloped surface dug toward a preparation scheduled portion of the lamella 12 on the sample S. The processing process of the slope 13 (step S22) may be referred to as a process of preparing a sloped surface. The processing of the slope 13 may also be referred to as a roughing process of preparing the lamella 12 from the sample S. Here, the angle of the sloped surface of the slope 13 is set to an angle larger than the measurement limit of the white light interference microscope 15 that performs the microscopic measurement.

Further, in order to facilitate the separation of the lamella 12 according to specifications such as strength and shape of the tweezers 27, a side portion 12SS and a bottom portion 12BO of the lamella 12 are cut by etching while leaving a support portion 12a.

### Step S3: Mark Processing Process

After the processing of the slope 13, the first control device 201 performs irradiation with the focused ion beam 9 and performs processing process of the mark 14 by etching by sputtering as illustrated in FIG. 12 (step S31). In this example, four circular marks SPT are formed on the surface of one slope 13 as the marks 14. When the mark 14 is the circular mark SPT, spot processing is performed. When the mark 14 is the linear mark LIN, line processing is performed. When the mark 14 is the rectangular mark REC, rectangular processing is performed. The mark 14 may be formed by applying a deposition film. The mark processing process (step S31) may be referred to as a process of performing mark processing at one or more portions on the surface of the sloped surface of the slope 13 in order to increase the surface roughness of the surface.

Thereafter, a finishing process (step S32) is performed. In the finishing process (step S32), the lamella 12 is cut to a final required thickness, thereby exposing a surface of the lamella 12 to be observed by TEM.

In order to prevent the lamella 12 from being contaminated due to redeposition caused by the processing of the mark 14, the processing of the mark 14 is performed after the preparation processing of the slope 13 (step S2) and before the finishing process of cutting the lamella 12 to the final required thickness (step S32). That is, after the processing of the slope 13 (step S2), the processing of the mark 14 (step S31) is performed, and then the finishing process (step S32) is performed. Although a shape and a depth of the processing of the mark 14 are not limited, it is desirable that a size of processing of the mark 14 is larger than the detection resolution of the lamella lift-out apparatus 2. When estimating a three-dimensional shape, it is necessary to prepare three or more marks 14 per one surface of the slope.

### Step S4: Conveyance to Lamellar Lift-Out Apparatus

After the processing of the mark 14, the operator moves the sample S from the FIB-SEM composite apparatus 1 and places the sample S on the sample stage 26 of the lamella lift-out apparatus 2.

### Step S5: Movement to TEM Sample Processing Region

After the sample S is placed on the lamella lift-out apparatus 2, the second control device 29 controls the sample stage 26 and the tweezers drive mechanism 28 while referring to a signal output from the photodetector 24, and moves the sample S and the tweezers 27 so that the lamella processing region B of the sample S and tip portions of the tweezers 27 are simultaneously detected in a microscopic image output from the photodetector 24 of the lamella lift-out apparatus 2.

### Step S6: Acquisition of Mark Position Information

Next, the mark 14 is subjected to microscopic measurement by the white light interference microscope 15 to acquire surface information of the lamella processing region B of the lamella 12 and the slope 13. The second control device 29 performs microscopic measurement on positions of the sample S and the tweezers 27 in the Z-axis direction based on a signal of the microscope image output from the photodetector 24 while moving the white light interference microscope 15 in the Z-axis direction by the lens barrel drive mechanism 25. FIG. 13 is a conceptual diagram illustrating a case where the light L1 described with reference to FIG. 5 is applied to the sloped surface of the slope 13 and the recessed fine processing surface (14S1) of the mark 14.

The light L1 applied to the sloped surface of the slope 13 becomes, for example, reflected light L1R2 reflected in a horizontal direction. The reflected light L1R2 is light that does not reach the photodetector 24. On the other hand, the light L1 applied to the recessed fine processing surface of the mark 14 becomes, for example, reflected light L1R1 reflected in a vertical direction. In addition, the light L1 is also applied to the surface of the lamella 12, and becomes reflected light L1R1 reflected on the surface of lamella 12, for example, in the vertical direction. The reflected light L1R1 can be combined with the reference light L2 and reach the photodetector 24 as the interference light L3. Accordingly, the second control device 29 can grasp information on the positions (X-axis direction, Y-axis direction) of the lamella 12 and the slope 13 and information on the sloped surface of the slope 13 in the Z-axis direction.

FIG. 7 illustrates a microscopic image of the tweezers 27 and the lamella processing region B of the lamella 12 obtained by the lamella lift-out apparatus 2. FIG. 7 is a result of a microscopic image obtained by measurement. In FIG. 7, an image 114 as a microscopic image corresponds to the processed mark 14. For each of the image 114, an image 112 that is a microscopic image corresponding to the surface of the lamella 12, an image 110 that is a microscopic image corresponding to a periphery of the lamella processing region B, and an image 115 that is a microscopic image corresponding to an upper surface of the tweezers 27, position information (X-axis direction, Y-axis direction, Z-axis direction) of a three-dimensional shape is acquired.

### Step S7: Estimation of Shapes of Processing Region and Tweezers Based on Position Information of Sample and Tweezers

Next, a three-dimensional shape of the sample S is estimated from the acquired surface information. For the tweezers 27, the obtained image 115 is used for the shape of the upper surface, and a three-dimensional shape and an existence position thereof are estimated using known attachment angle information and dimension data. For the sample S, the position information in the obtained image is used as it is for the surface 11 of the lamella processing region B of the sample S and an upper surface of the lamella 12, and the sloped surface of the slope 13 is fitted as a three-dimensional plane using the position information in the image 114 of the mark 14, thereby estimating surface shapes of the surface 11 of the sample S, the lamella 12, and the sloped surface of the slope 13 and existence positions thereof.

A distance between the tweezers 27 and the lamella processing region B of sample S is estimated using the shape and position data of the surface 11 of the lamella processing region B of the sample S, the lamella 12, and the sloped surface of the slope 13 determined as described above.

### Step S8: Movement of Tweezers Based on Estimated Shape

The second control device 29, which is a control unit, moves the tweezers 27 to a position (a position immediately before the gripping position of the lamella 12 by the tweezers 27), where the lamella 12 can be gripped by the tweezers 27 by closing the tweezers 27 and the distance between the tweezers 27 and the lamella is the shortest in a range in which the tweezers 27 and the lamella are not in contact with each other, by the tweezers drive mechanism 28 according to the obtained distance between the lamella processing region B and the tweezers 27. FIG. 14 is a conceptual diagram illustrating a state in which the tweezers 27 are moved to the position immediately before the gripping position of the lamella 12.

Step S8 can be regarded as a process of controlling the sample stage 26 on which the sample S is placed or the tweezers 27 to reduce a distance between the estimated shape of the surface of the sloped surface of the slope 13 (the position of the mark 14) and the position of the tweezers 27 serving as the lamella transfer part.

That is, the lamella lift-out apparatus 2, which is the lamella extraction apparatus, performs a process of simultaneously measuring the tweezers 27, which are the lamella transfer part, and the lamella processing region B of the lamella 12 with the scanning white light interference microscope 15 to acquire coordinates of the tweezers 27, the mark 14 and the upper surface of the lamella 12, and controlling the tweezers 27 such that the distance between the tweezers 27 and the mark 14 is small and the tweezers 27 do not come into contact with the mark.

### Step S9: Pickup of Sample

After the movement, the second control device 29 closes the tweezers 27 to grip the lamella 12, and moves or rotates the tweezers 27 in any direction by the tweezers drive mechanism 28 to separate the lamella 12 from the sample S.

After separating the lamella 12, the second control device 29 retracts the tweezers 27 in the Z-axis direction by the tweezers drive mechanism 28 to a height at which the tweezers 27 do not come into contact with the sample S.

### Step S10: Movement of Stage to TEM Mesh

After the retraction of the tweezers 27, the second control device 29 drives the sample stage 26 and the tweezers drive mechanism 28 while referring to the microscopic image obtained from the photodetector 24 so that the lamella 12 exists above a lamella placement position on the TEM observation lamella holder 32.

### Step S11: Placement of Sample (Lamella 12) on TEM Mesh

Thereafter, the tweezers drive mechanism 28 is lowered in the Z-axis direction until the lamella 12 and the TEM observation lamella holder 32 come into contact with each other. That is, the lamella lift-out apparatus 2, which is the lamella extraction apparatus, picks out (extracts) the lamella 12 from the sample S and transfers and places the lamella 12 onto the lamella holder 32 by a process of controlling the tweezers 27 so that XY coordinates of the upper surface of the lamella 12 and a tip of the tweezers 27 (the portion of the tweezers 27 gripping the lamella 12) coincide with each other.

Since the mesh 34 of the TEM observation lamella holder 32 is deformed with the contact of the object (lamella 12), the distance of the optical path of the light L1 is changed, and the intensity of the interference light L3 is changed, so that the microscopic image output from the photodetector 24 is changed. Accordingly, contact determination of whether the lamella 12 and the mesh 34 are in contact with each other is performed by detecting the change. After the contact with the TEM observation lamella holder 32, the tweezers are opened, and the lamella 12 is placed on the TEM observation lamella holder. This process completes the lamella lifting-out.

Thereafter, the Operator Transfers the Tem Observation lamella holder 32 having the lifted-out lamella 12 from the lamella lift-out apparatus 2 to the TEM apparatus 3. The TEM observation of the lamella 12 is performed by the TEM apparatus 3.

According to the embodiment, even when the sloped surface (the surface of the slope 13) prepared by the processing of the lamella 12 is sloped to be larger than the opening angle of the optical system of the photodetector 24 using the white light interference microscope 15 as an observation unit, the mark 14 is formed on the surface of the slope 13, so that the surface (14S, 14S1, 14S2) different from the surface (also referred to as a sloped surface or a slope surface) of the slope 13 is formed. Therefore, even when the reflected light L1R by the surface of the slope 13 does not fall within the range of angles up to the maximum angle θ , the reflected light L1R falls within the range of angles up to the maximum angle θ by the surface 14S formed by the mark 14.

As a result, the second control device 29 can grasp the information on the position (X-axis direction, Y-axis direction) of the lamella 12 and the information on the slope 13 in the Z-axis direction (height direction) from the photodetector 24 of the white light interference microscope 15.

Since the second control device 29 can grasp the information on the position (X-axis direction, Y-axis direction) of the lamella 12 and the information on the slope 13 in the Z-axis direction (height direction), the tweezers 27 used for pickup can be moved to the position immediately before the gripping position of the lamella 12 by the tweezers 27 without being brought into contact with the sample processing region B (lamella processing region of the lamella 12).

Therefore, safe lifting-out of the lamella 12 from the sample S can be performed.

### Modifications

Hereinafter, modifications of Embodiment 1 will be described. A description of the same processes as those in the above-described embodiment will be omitted or simplified.

Although it is assumed that the operation of the FIB-SEM composite apparatus 1 is performed by the operator in the configuration of Embodiment 1, the operation can be performed by registering steps of the operation in the operation control program for the automatic operation control processing in the first control device 201, whereby the FIB-SEM composite apparatus 1 can automatically perform each step.

Although it is assumed that the operation of the lamella lift-out apparatus 2 is performed by the operator in the configuration of Embodiment 1, the operation can be performed by registering steps of the operation in the operation control program for automatic operation control processing in the second control device 29, whereby the lamella lift-out apparatus 2 can automatically perform each step.

Although the FIB-SEM composite apparatus 1 including the irradiation optical system 4 of the focused ion beam 9 and the irradiation optical system 5 of the electron beam 10 is used in the configuration of Embodiment 1, the invention is not limited thereto. For example, only a focused ion beam apparatus without the irradiation optical system 5 of the electron beam 10 may be used.

Although the white light interference microscope 15 uses, as an interference mechanism, a Linnik interferometer including two objective lenses of the first objective lens 20 and the second objective lens 21 in the configuration of Embodiment 1, the invention is not limited thereto. For example, a Michelson interferometer or a Mirau interferometer may be used.

Although a circular object is used as the TEM observation lamella holder 32 in the configuration of Embodiment 1, the invention is not limited thereto. The grid frame 33 may have a semicircular shape or the like.

Although the mark processing is performed using sputtering in Embodiment 1, the invention is not limited thereto. The mark processing may be performed by deposition.

Although the mark processing is performed on the lamella processing region B in Embodiment 1, the object to which the mark 14 is applied is not limited to the slope 13. For example, the mark 14 may be attached to the tweezers 27. As illustrated in FIG. 8, when the inclination of tweezers 116 is larger than a measurement limit angle, the reflected light (L1R) from the tweezers cannot be detected. Therefore, by attaching a mark 117 to the tweezers 116, a mark region can be measured by the microscope, and position of the tweezers 116 can be grasped.

Further, by attaching the mark (14, 117) not only to the tweezers but also to an object having an inclination angle larger than the measurement limit angle, information on the position (Z-axis direction, height direction) can be grasped. Also in this case, the mark processing of the mark (14, 117) can be performed by sputtering or deposition.

The invention is not limited to the above-described embodiments, and modifications, improvements, and the like can be made as appropriate. In addition, any material, shape, dimension, numerical value, form, number, arrangement position, and the like of each component in the above-described embodiment can be adopted and are not limited as long as the invention can be achieved.

### REFERENCE SIGNS LIST

1: FIB-SEM composite apparatus
2: lamella lift-out apparatus
3: TEM apparatus
7: gas gun (deposition gas supply part)
12: lamella
13: slope
14: mark
15: white light interference microscope
25: lens barrel drive mechanism
26: sample stage
27: tweezers
114: microscopic image of mark
100: lamella observation system

1. A beam apparatus that prepares a mark on a sloped surface dug toward a lamella prepared in a sample by lamella preparation processing.

2. A lamella extraction apparatus comprising:
a sample stage configured to allow a sample to be placed thereon;
a lamella transfer part configured to transfer a lamella from the sample;
a microscope configured to acquire surface information by observing a mark prepared on the sample; and
a control unit configured to control the sample stage or the lamella transfer part to reduce a distance between a position of the mark and a position of the lamella transfer part.

3. A lamella observation system comprising:
a beam apparatus configured to prepare a mark on a sloped surface dug toward a lamella prepared in a sample by lamella preparation processing;
a lamella extraction apparatus including a microscope for observing the mark, and configured to observe the mark and extract the lamella from the sample based on the mark; and
a transmission electron microscope configured to observe the extracted lamella.

4. The lamella observation system according to claim 3, wherein
the sloped surface has a surface sloped with respect to an optic axis of light emitted by the microscope.

5. The lamella observation system according to claim 3, wherein
the beam apparatus is a focused ion beam apparatus that prepares a sample for the transmission electron microscope by performing irradiation with a focused ion beam.

6. The lamella observation system according to claim 5, wherein
the focused ion beam apparatus is an FIB-SEM apparatus including a scanning electron microscope lens barrel.

7. The lamella observation system according to claim 3, wherein
the lamella extraction apparatus includes, as an observation unit, a scanning white light interference microscope on which a light source, an interferometer, and a detector are mounted and which acquires height information from a distribution of detected interference fringes.

8. The lamella observation system according to claim 7, wherein
the lamella extraction apparatus extracts the lamella and transfers and places the lamella onto a lamella holder by
a process of simultaneously measuring a lamella transfer part and a lamella processing region with the scanning white light interference microscope to acquire coordinates of the lamella transfer part, the mark, and an upper surface of the lamella, and controlling the lamella transfer part such that a distance between the lamella transfer part and the mark is small and the lamella transfer part does not come into contact with the mark, and
a process of controlling the lamella transfer part such that XY coordinates of the upper surface of the lamella and the lamella transfer part coincide with each other.

9. A lamella preparation method for extracting the lamella from the sample by using the lamella transfer part in the lamella observation system according to claim 3, the method comprising:
a mark preparation process of preparing the mark on a sloped surface dug toward the lamella prepared in the sample by lamella preparation processing;
a process of acquiring surface information by performing microscopic measurement on the mark;
a process of estimating a three-dimensional shape of the sample from the acquired surface information; and
a process of controlling the sample or the lamella transfer part to reduce a distance between an estimated surface of the sloped surface and a position of the lamella transfer part.

10. The lamella preparation method according to claim 9, further comprising:
a roughing process of preparing the lamella from the sample; and
a finishing process of exposing a surface to be observed by TEM, wherein
the mark preparation process is performed before the finishing process.

11. The lamella preparation method according to claim 9, wherein
an angle of the sloped surface is an angle larger than a measurement limit of the microscope that performs microscopic measurement.

12. The lamella preparation method according to claim 9, wherein
the mark preparation process includes
a process of preparing the sloped surface,
a mark processing process of performing mark processing at one or more portions on the surface of the sloped surface in order to increase surface roughness of the surface, and
a process of performing finishing after the mark processing process.

13. The lamella preparation method according to claim 9, wherein
the mark preparation process includes spot processing of forming the mark having a spot shape.

14. The lamella preparation method according to claim 9, wherein
the mark preparation process includes line processing of forming the mark having a line shape.

15. The lamella preparation method according to claim 9, wherein
the mark preparation process includes rectangular processing of forming the mark having a rectangular shape.

16. The lamella preparation method according to claim 9, wherein
the mark preparation process includes etching or deposition.
